(19) United States
(12) Patent Application Publication
(10) Pub. No.: US 2002/0011664 A1
(43) Pub. Date: Jan. 31, 2002

(54) Semiconductor element, manufacturing method thereof and BGA-type semiconductor device

(75) Inventor: Rika Tanaka, Tokyo (JP)

Correspondence Address: Norman P. Soloway, HAYES, SOLOWAY, HENNESSEY,, GROSSMAN & HAGE, P.C., 175 Canal Street, Manchester, NH, 03101, US

(73) Assignee: NEC Corporation

(21) Appl. No.: 09/915,728

(22) Filed: Jul. 26, 2001

(30) Foreign Application Priority Data
Jul. 27, 2000 (JP) 2000-226347

(51) Int. Cl. H01L 23/48; H01L 23/52; H01L 29/40

(52) U.S. Cl. 257/734

(57) ABSTRACT

A semiconductor element is provided with a semiconductor substrate with an integrated circuit to which external electrodes are connected. The external electrodes are made of at least one layer selected from among a copper layer, a Sn—Cu alloy layer and a Sn—Ag alloy layer.

### BACKGROUND OF THE INVENTION

1. Field of the Invention

The present invention relates to a semiconductor element that is mounted on a circuit board, for example, by the flip-chip method, their manufacturing methods, and BGA (Ball Grid Array)-type semiconductor device equipped with such a semiconductor element. The present invention relates more specifically to a semiconductor element of which erroneous operations are prevented, its manufacturing methods, and a BGA-type semiconductor device equipped with such a semiconductor element.

2. Description of the Related Art

A semiconductor element has, for example, metallic studs or metallic bumps as external terminals. Such a semiconductor element is incorporated in a BGA (ball grid array)-type or MCM (multi chip module)-type semiconductor device. The semiconductor element is mounted on a circuit board by a CIB (chip in board), a COB (chip on board) or a TAB (tape automated bonding) method. A number of metallic bumps and metallic studs have been proposed, and in general, solder bumps are frequently used.

FIG. 1 is a sectional view of a prior art semiconductor element with a flip-chip structure and solder bumps. Pads 2 connected to the inner circuit are formed on a semiconductor substrate 1 which has an activated area 7. The semiconductor substrate 1 is coated with a dielectric layer 3 serving as a passivation film. The dielectric layer 3 has openings in positions corresponding to each pad 2. A barrier metal 5 is evaporated on each pad 2 by using a metal mask (not shown). On the barrier metal 5, a solder bump 6 is formed. The solder bump 6 is formed by evaporating Sn and Pb, and then heating them to fuse them.

The solder bump 6 contains Pb, and the Pb contains radioactive impurities, such as Uranium (U) and Thorium (Th), that emit α-rays in concentrations of around 100-1000 ppb(10⁻⁹). If the activated area 7 is irradiated by α-rays, so called soft error occurs. This is a phenomenon where the memory contents are destroyed with no physical destruction of the device structure. Therefore, the solder bumps 6 should be located away from the activated area 7. Consequently, the number of mountable solder bumps 6 is limited.

On the other hand, if the concentration of radioactive impurities is reduced to 50 ppb or lower, soft error can be prevented even if solder bumps are formed on the whole area of the substrate. However, in order to reduce the concentration of radioactive impurities down to 50 ppb or lower, refined Sn and Pb should be used. Refining the Sn and PB causes the price of the solder that has been refined to rise from several to several tens of times that of the solder that has not been refined. If solder bumps are formed with such expensive solder in a semiconductor element with 1000 pins or more, the price of such a semiconductor device becomes very high.

Japanese Patent Laid-Open Publication No. Hei.11-87387 has disclosed a semiconductor element that may solve the above problems. FIG. 2 is a sectional view of a semiconductor element of the same structure as that disclosed in the Japanese Patent Laid-Open Publication No. Hei.11-87387. In the prior art semiconductor element shown in FIG. 2, the same components as those in FIG. 1 have the same reference numbers and their detailed explanations are not repeated.

The prior art semiconductor element shown in FIG. 2 has solder bumps 4 inside the activated area 7 and solder bumps 6 outside of the activated area 7. The material of the solder bump 4 (low α-ray solder) contains less radioactive impurities than that of the solder bump 6.

In the prior art semiconductor element, the number of solder bumps 4, of which the cost is relatively high because of the refining treatment of the radioactive impurities, can be minimized. As a result, the cost increase is prevented and solder bumps can be located over a wide area on the substrate.

In recent years, environmental destruction has been recognized as a serious problem in the world. Private companies are not allowed to neglect environmental issues. In fact private companies are required to be eager to solve environmental problems. Therefore, to prevent soft error and for the protection of the environment, it is important to develop solder without Pb. In the semiconductor element shown in FIG. 2, it is possible to prevent α-rays from causing soft error. However, two kinds of solder balls with different concentrations of radioactive impurities must be located separately. Consequently, the manufacturing process of the device and material handling become complex. In addition, since solder containing Pb is employed, the environmental problem remains unsolved. The above patent publication refers to a method for forming gold plated bumps in the positions corresponding to activated areas. Consequently, another problem arises in that the manufacturing cost becomes very high.

### SUMMARY OF THE INVENTION

It is therefore an object of the present invention to provide a semiconductor element that can prevent erroneous operation of the semiconductor device due to soft error, its manufacturing method, and a BGA-type semiconductor device. A second object of the invention is to provide an inexpensive, environmentally friendly semiconductor element, its manufacturing method, and a BGA-type semiconductor device.

According to one aspect of the present invention, a semiconductor element comprises a semiconductor substrate with an integrated circuit and an external terminal connected to the integrated circuit. The external terminal is composed of at least one layer selected from the group consisting of a copper layer, a Sn—Cu alloy layer and a Sn—Ag alloy layer.

According to another aspect of the present invention, a semiconductor element manufacturing method comprises the steps of: forming a passivation film on a semiconductor substrate with an integrated circuit and a metallic electrode connected to the integrated circuit, the metallic electrode being not covered by the passivation film but exposed; depositing at least one metallic film selected from the group consisting of a Pb-free low melting point metallic film and a composite film of a barrier metal film and a Pb-free low melting point metallic film; forming a pad by patterning the metallic film; forming a metallic stud made of at least one metallic layer selected from the group consisting of a Cu layer, a Sn—Cu alloy layer and a Sn—Ag alloy layer on a second substrate with a conductive surface; overlaying the second substrate with the semiconductor substrate by positioning the metallic stud over the pad; connecting the pad and the metallic stud by conducting reflow of the low melting point metallic film; and removing the second substrate.

According to another aspect of the present invention, a semiconductor element manufacturing method comprises the steps of: forming a passivation film on a semiconductor substrate with an integrated circuit and a metallic electrode connected to the integrated circuit, the metallic electrode being not covered by the passivation film but exposed; depositing a plating base layer on a whole surface of the semiconductor substrate; forming a mask layer with an opening over the metallic electrode on the plating base layer; forming a metallic stud made of at least one metallic layer selected from the group consisting of a Cu layer, a Sn—Cu alloy layer and a Sn—Ag alloy layer in the opening; and removing the mask layer and a portion of the plating base layer covered by the mask layer.

According to another aspect of the present invention, a BGA-type semiconductor device comprises a mounting substrate and a semiconductor element mounted on the mounting substrate. The semiconductor element has a semiconductor substrate with an integrated circuit and an external terminal connected to the integrated circuit. The external electrode is composed of at least one layer selected from the group consisting of a copper layer, a Sn—Cu alloy layer and a Sn—Ag alloy layer and connected to the mounting substrate.

In the present invention, a metallic stud is made of, for example, materials that emit few α-rays. Therefore, erroneous operation of the semiconductor element due to soft error can be prevented. In addition, since the metallic stud does not contain Pb, it serves to protect the environment.

If the stud is 20 μm tall or more, the effect of α-rays can be eliminated even if the conductive layer such as a solder layer formed under the metallic stud emits α-rays.

### BRIEF DESCRIPTION OF THE DRAWINGS

FIG. 1 is a sectional view of a prior art semiconductor element of a flip-chip structure with solder bumps.

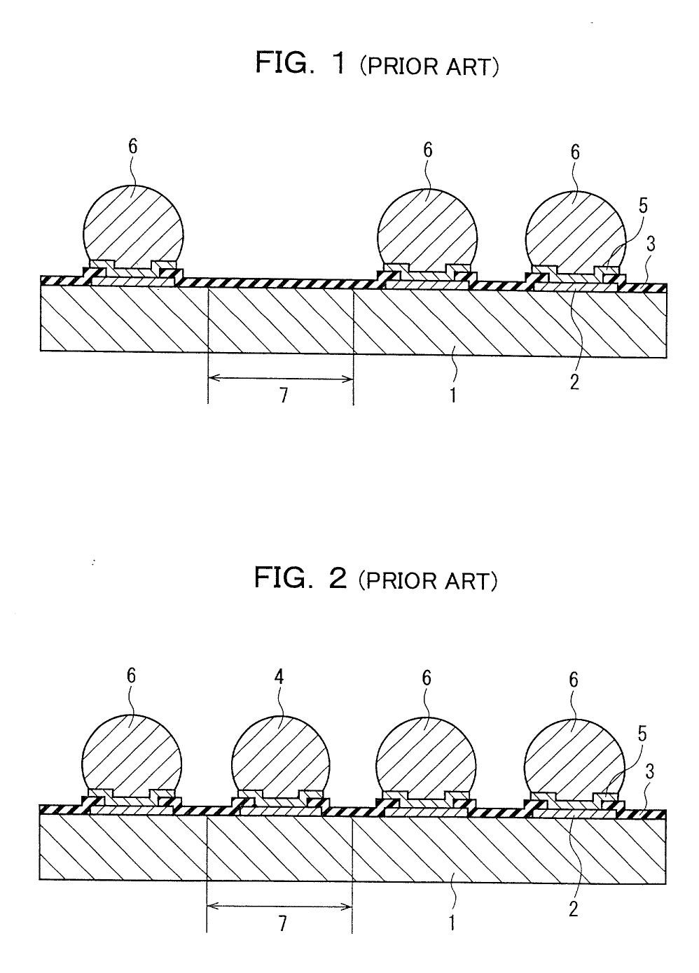

FIG. 2 is a sectional view of a semiconductor element with the same structure disclosed in Japanese Patent Laid-Open Publication No. Hei.11-87387.

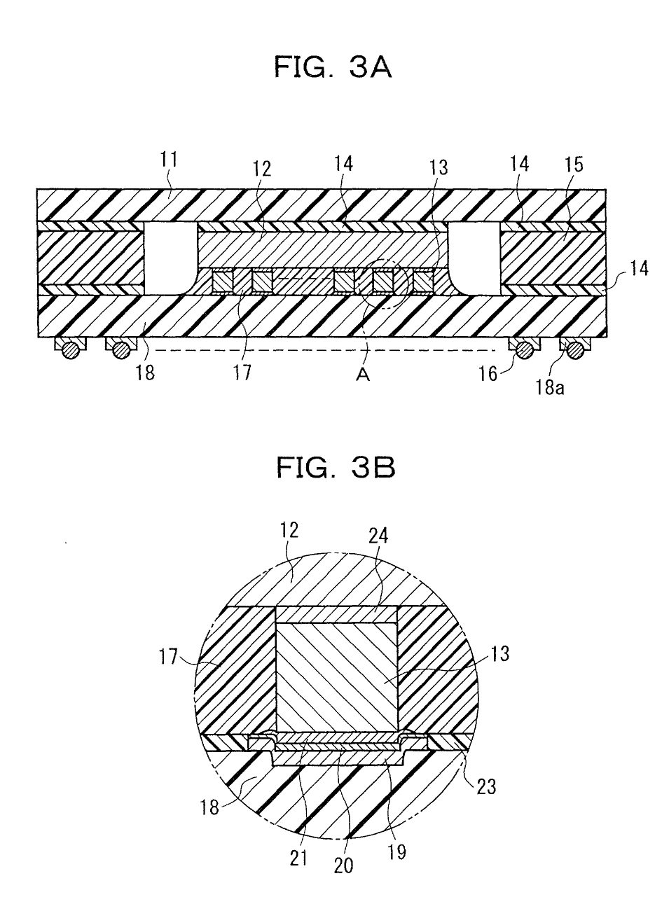

FIG. 3A is a sectional view of a FCBGA (flip chip ball grid array)-type semiconductor device according to a first embodiment of the present invention, and FIG. 3B is an enlarged view of an area circled in FIG. 3A.

FIGS. 4A-4H are sectional views of each of the process steps which illustrate the manufacturing method of the FCBGA-type semiconductor device according to the first embodiment of the present invention.

FIGS. 5A-5D are sectional views of each of the process steps which illustrate the manufacturing method of the flip-chip semiconductor element according to a second embodiment of the present invention.

FIG. 6 is a sectional view of the FCBGA-type semiconductor device according to a third embodiment of the present invention.

FIGS. 7A-7D are sectional views of each of the process steps which illustrate the manufacturing method of the FCBGA-type semiconductor appatarus according to a third embodiment of the present invention.

### DETAILED DESCRIPTION OF THE PREFERRED EMBODIMENT

The preferred embodiments of the present invention will be described below with reference the accompanying drawings.

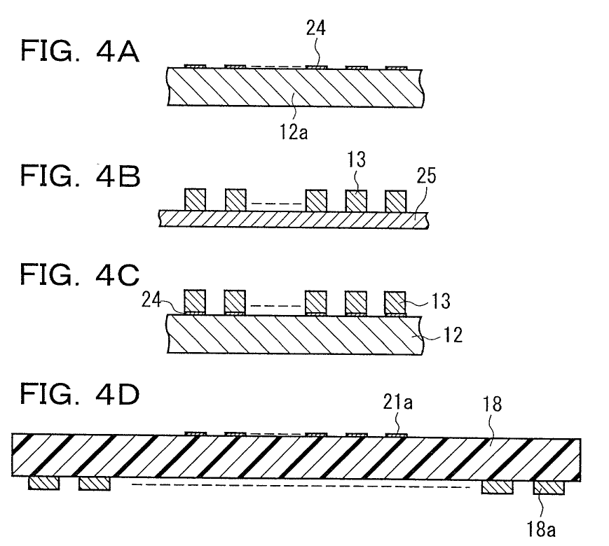

FIG. 3A is a sectional view of a FCBGA (flip chip ball grid array)-type semiconductor device according to a first embodiment of the invention, and FIG. 3B is an enlarged view of an area circled in FIG. 3A.

An integrated circuit (not shown) is formed on a surface (circuit bearing side) of a semiconductor substrate 12. Pads 24 connected to the integrated circuit are formed on the circuit bearing side. Further, metallic studs 13 (external terminal) are formed on the pads 24. The height of the metallic stud 13 is, for example, at least 20 μm. The semiconductor element is thereby constructed. The metallic stud 13 may be made of, for example, a Cu layer, a Sn—Cu alloy layer or a Sn—Ag alloy layer, or a lamination of the aforementioned layers.

Concave parts are formed on a surface of a mounting substrate 18. In each concave part a Cu electrode 19 is formed, while a Ni/Au plated layer 20 and a solder layer 21 are formed on the Cu electrode 19. The metallic stud 13 is connected to the solder layer 21. The surface of the mounting substrate 18, other than the areas connected to the metallic stud 13, is covered with a solder resist 23.

Electrode pads 18a is formed on the underside of the mounting substrate 18. A solder ball 16 is fixed on each electrode pad 18a. The metallic stud 13 is connected to the solder ball 16 via the electrode pad 18a. In order to protect the package contents from dust and humidity, spacers 15 and a cover plate 11 are bonded with an adhesive 14. A hermetic structure is constituted with the cover plate 11, spacers 15 and mounting substrate 18 and the like.

The gap between the semiconductor substrate 12 and the mounting substrate 18 is filled with a filling resin 17.

In the first embodiment of the invention of the above configuration, since the metallic stud 13 and filling resin 17 exist in between the solder layer 21 and the semiconductor substrate 12, the α-rays emitted from the solder layer 21 almost disappear before reaching the semiconductor substrate 12.

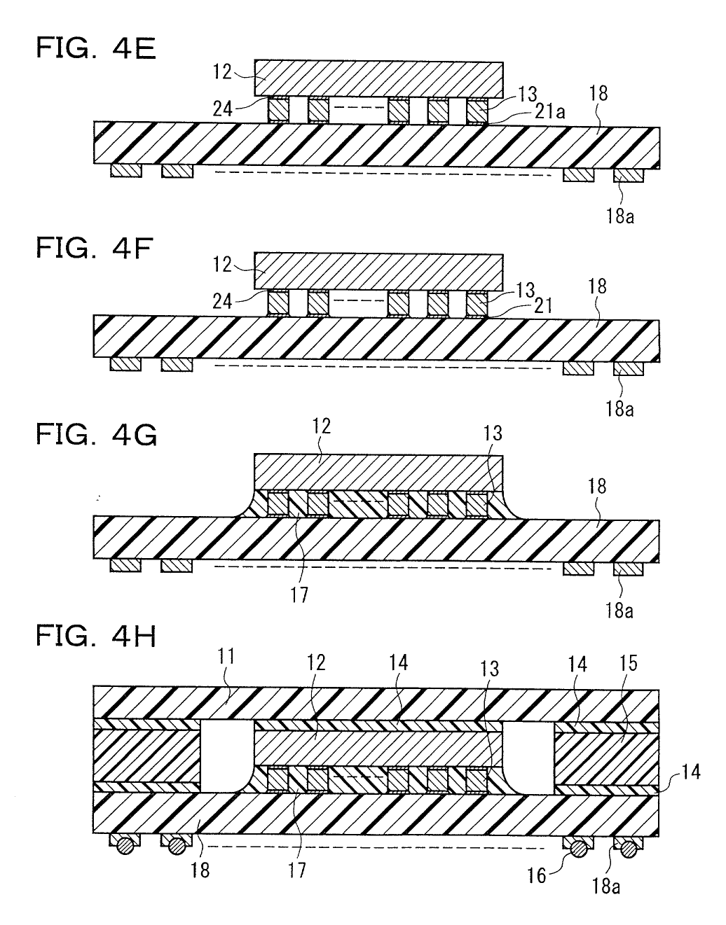

Next, the manufacturing method of the FCBGA-type semiconductor device according to the first embodiment of the invention is described. FIGS. 4A-4H are sectional views of each of the process steps which illustrate the manufacturing method of the FCBGA-type semiconductor device according to the first embodiment of the present invention.

First, Al electrodes (not shown) are formed on the circuit-bearing surface of a semiconductor wafer 12a in which an integrated circuit (not shown) is formed. Next, a dielectric layer (not shown) with openings in the positions corresponding to the Al electrodes is formed over the whole wafer surface as a passivation film. Then a TiW film, which is a barrier metal film, and a Sn—Ag solder, which is a low melting point metallic film, are deposited, by spattering, over the whole surface. The formation of a barrier metal film is not essential. Later, as shown in FIG. 4A, pads 24 are formed by photo-etching. Next, the semiconductor wafer 12a is cut into individual chips, by scribing, to provide semiconductor substrates 12.

In a separate process, a Cu layer, a Sn—Cu alloy layer or a Sn—Ag alloy layer, or a layer formed from the lamination of the aforementioned layers is deposited by the electrolytic plating method on, for example, a metallic transferring substrate 25 by the use of a mask (not shown) with openings in the positions corresponding to the pads 24. As a result, metallic studs 13 with, for example, a diameter of 100-150 μm and a height of at least 20 μm are formed as shown in FIG. 4B.

If the metallic studs 13 are shorter than 20 μm, the energy of the α-rays entering the semiconductor substrate may not decrease to a required level. In addition, the filling process, which will be described later, of the filling resin 17 may be difficult to perform.

Later, the pads 24 on the semiconductor substrate 12 are positioned over the metallic studs 13 using a flip-chip mounter (not shown), and the studs 13 are connected to the pads 24 by reflow as shown in FIG. 4C. Subsequently, the transferring substrate 25 is removed by etching.

Next, as shown in FIG. 4D, a solder paste 21a is screen-printed via a metal mask onto the positions on a mounting substrate 18 where bumps are to be formed. The solder paste 21a may be a conventional one, because the amount used is very small and the occurrence of soft error can be prevented by the shielding effect of the metallic studs 13 and filling resin 17. If a solder material of which the concentration of radioactive impurities is, for example, 50 ppb or lower is employed, or a solder paste containing no Pb is employed, the probability of the occurrence of soft error is further reduced.

After the screen printing, the semiconductor substrate 12 where the metallic studs have been printed is mounted on the mounting substrate 18, as shown in FIG. 4E, with each metallic stud 13 located on the solder paste 21a.

Then as shown in FIG. 4F, the metallic studs 13 are connected to the mounting substrate 18, while the solder paste 21a is converted into a solder layer 21 by reflow.

Next, as shown in FIG. 4G, the gap between the semiconductor substrate 12 and the mounting substrate 18 is filled with the filling resin 17, and the filling resin 17 is cured.

All the parts on the substrate are packaged by bonding the spacers 15 and the cover plate 11 with the adhesive 14. Referring to FIG. 4H, the solder balls 16 are fixed on the electrode pads 18a of the mounting substrate 18.

The semiconductor device according to the first embodiment may be thereby fabricated.

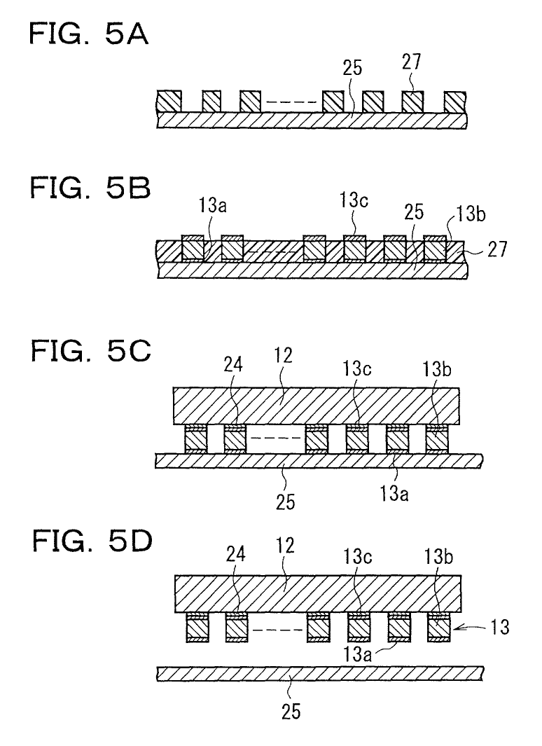

Next, the manufacturing method of the flip-chip type semiconductor element according to a second embodiment of the present invention is described. FIGS. 5A-5D are sectional views of each of the process steps that illustrate the manufacturing method of the flip-chip type semiconductor element according to the second embodiment of the present invention.

First, a resist mask 27 is formed on, for example, a metallic transferring substrate 25, by photolithography as shown in FIG. 5A, with a pattern excluding the areas corresponding to the pads on the semiconductor substrate.

Next, as shown in FIG. 5B, a solder plating layer 13a made of Sn solder containing 3.5% Ag by weight, a Cu plating layer 13b and a solder plating layer 13c made of Sn solder containing 5% Ag by weight are layered, in this order by electroplating, on the openings in the resist mask 27.

Then the resist mask 27 is removed. Subsequently, as shown in FIG. 5C, the semiconductor substrate 12, which has been fabricated by the same method as the first embodiment, is mounted on the transferring substrate 25, with the pads 24 being located on the metallic studs 13.

Later the solder plating layers 13a and 13c are fused and then cooled down. During cooling, the transferring substrate 25 is pulled off the semiconductor element, as shown in FIG. 5D. This is done when the transferring substrate 25 has cooled down to, for example, 225° C. At 225° C., the solder plating layer 13a is in a liquid state, while the solder layer 13c is in a solid state.

The semiconductor element according to the second embodiment may be thereby fabricated. The FCBGA-type semiconductor device can be manufactured by adopting the same manufacturing process as that used in the first embodiment.

In the second embodiment, the solder plating layer 13c made of Sn solder containing 5% Ag by weight is connected to the pad 24. However, the layer formed in between the pad 24 and the Cu plating layer 13b may be made of a highly conductive material such as a barrier metal or Cu. The pads 24 itself may be made of Sn solder containing 5% Ag by weight and the solder plating layer 13c may be omitted.

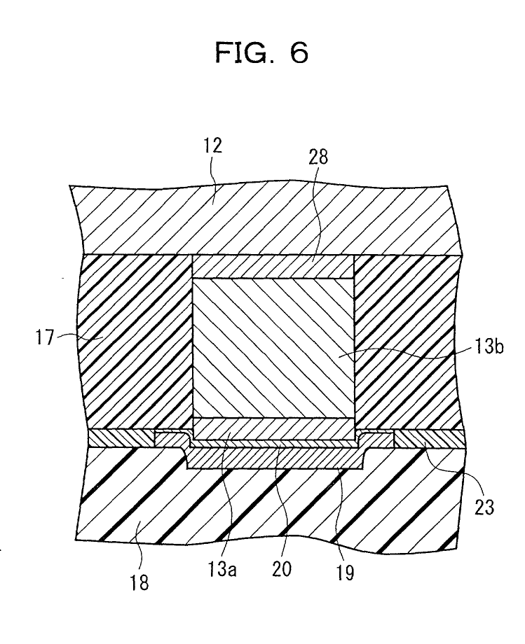

Next, a third embodiment of the invention is described. FIG. 6 is a sectional view of the FCBGA-type semiconductor device according to the third embodiment of the present invention. FIG. 6 is an enlarged view of FIG. 3B.

In the third embodiment, the pads of the semiconductor element are formed by a plating base coat 28. The metallic studs 13 have the Cu plating layer 13b and the solder plating layer 13a. Further, the solder layer 13a is soldered directly onto the Ni/Au plating layer 20 of the mounting substrate 18. These are the points of difference between the third embodiment and the first embodiment.

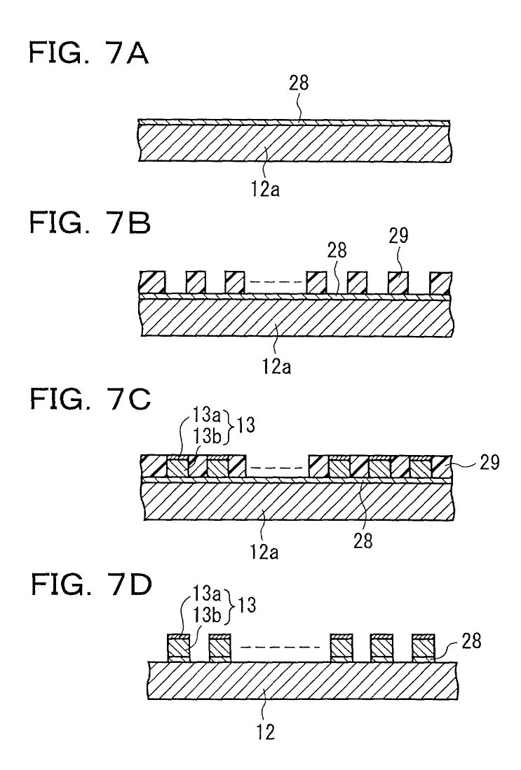

Next, the manufacturing method of the FCBGA-type semiconductor device according to the third embodiment of the invention is described. FIGS. 7A-7D are sectional views of each of the process steps which illustrate the manufacturing method of the FCBGA-type semiconductor device according to the third embodiment of the present invention.

First, Al electrodes (not shown) are formed on the circuit-bearing surface of the semiconductor wafer 12a. Then on the wafer surface, the passivation film (not shown) is formed that has openings in positions corresponding to the Al electrodes. A Ti/TiN barrier metal is formed by sputtering, and on this layer Cu is further deposited to form the plating base coat 28, as shown in FIG. 7A.

Next referring to FIG. 7B, the resist mask 29 is formed that has openings in the same positions as the openings in the passivation film.

Then as shown in FIG. 7C, the Cu plating layer 13b and the solder plating layer 13a made of Sn—Ag solder are formed in this order in the openings of the resist mask 29 by electroplating.

Subsequently, the resist mask 29 is removed and the semiconductor wafer 12a is cut into individual semiconductor substrates 12, by scribing, to provide semiconductor elements of the flip-chip structure, as shown in FIG. 7D.

The semiconductor element may be thereby fabricated. In the fabrication of the semiconductor device according to the third embodiment, incorporating such a semiconductor element, the semiconductor element is first mounted on the mounting substrate 18 without solder paste. Then, the gap between the semiconductor substrate 12 and the mounting substrate 18 is filled with filling resin 17. Later, the same processes as those described in the first embodiment are carried out. The semiconductor device shown in FIG. 6 can be manufactured by these manufacturing processes.

The invention is not limited only to the above embodiments. It is apparent that various modifications and the like can be made without departing from the spirit of the invention. For example, the shape of the metallic stud may be other than a cylinder, for example, a prism. The metallic stud may be formed by electroless plating or evaporation. In the second embodiment, the transferring substrate 25 may be a dielectric substrate like glass on which there is a conductive layer. The mask material for electrolytic plating may be an inorganic film such as silicon oxide film, instead of the resist film. In the above embodiments the semiconductor element is mounted on the transferring substrate after it has been cut out of the wafer. However, the wafer itself may be first mounted on the transferring substrate and later cut into individual chips.

What is claimed is:

1. A semiconductor element, comprising:
a semiconductor substrate with an integrated circuit; and
an external terminal connected to said integrated circuit, said external terminal being composed of at least one layer selected from the group consisting of a copper layer, a Sn—Cu alloy layer and a Sn—Ag alloy layer.

2. The semiconductor element according to claim 1, wherein the height of said external terminal is at least 20 μm.

3. A semiconductor element manufacturing method, comprising the steps of:
forming a passivation film on a semiconductor substrate with an integrated circuit and a metallic electrode connected to said integrated circuit, said metallic electrode being not covered by said passivation film but exposed;
depositing at least one metallic film selected from the group consisting of a Pb-free low melting point metallic film and a composite film of a barrier metal film and a Pb-free low melting point metallic film;
forming a pad by patterning said metallic film;
forming a metallic stud made of at least one metallic layer selected from the group consisting of a Cu layer, a Sn—Cu alloy layer and a Sn—Ag alloy layer on a second substrate with a conductive surface;
overlaying said second substrate with said semiconductor substrate by positioning said metallic stud over said pad;
connecting said pad and said metallic stud by conducting reflow of said low melting point metallic film; and
removing said second substrate.

4. The semiconductor element manufacturing method according to claim 3, wherein said second substrate is removed by etching.

5. The semiconductor element manufacturing method according to claim 3, wherein said metallic stud is formed by the steps of forming the uppermost layer of said metallic stud with the Sn—Ag alloy and conducting reflow of said uppermost layer.

6. The semiconductor element manufacturing method according to claim 4, wherein said metallic stud is formed by the steps of forming the uppermost layer of said metallic stud with the Sn—Ag alloy and conducting reflow of said uppermost layer.

7. A semiconductor element manufacturing method, comprising the steps of:
forming a passivation film on a semiconductor substrate with an integrated circuit and a metallic electrode connected to said integrated circuit, said metallic electrode being not covered by said passivation film but exposed;
depositing a plating base layer on a whole surface of said semiconductor substrate;
forming a mask layer with an opening over said metallic electrode on said plating base layer;
forming a metallic stud made of at least one metallic layer selected from the group consisting of a Cu layer, a Sn—Cu alloy layer and a Sn—Ag alloy layer in said opening; and
removing said mask layer and a portion of said plating base layer covered by said mask layer.

8. The semiconductor element manufacturing method according to claim 7, wherein said plating base layer comprises a barrier metal film connected to said metallic electrode.

9. A BGA-type semiconductor device, comprising:
a mounting substrate; and
a semiconductor element mounted on said mounting substrate, said semiconductor element having:
a semiconductor substrate with an integrated circuit; and
an external terminal connected to said integrated circuit, said external electrode being composed of at least one layer selected from the group consisting of a copper layer, a Sn—Cu alloy layer and a Sn—Ag alloy layer and connected to said mounting substrate.

10. The semiconductor device according to claim 9, wherein a distance between said semiconductor substrate and said mounting substrate is at least 20 μmm.

11. The semiconductor device according to claim 9, wherein said external electrode comprises a solder layer as the uppermost surface containing no lead, said solder layer being connected to said mounting substrate.

12. The semiconductor device according to claim 10, wherein said external electrode comprises a solder layer as the uppermost surface containing no lead, said solder layer being connected to said mounting substrate.

13. The semiconductor device according to claim 9, wherein said external electrode comprises a low melting point metallic film as the uppermost surface containing radioactive impurities emitting α-rays in concentrations of 50 ppb or less, said low melting point metallic film being connected to said mounting substrate.

14. The semiconductor device according to claim 10, wherein said external electrode comprises a low melting point metallic film as the uppermost surface containing radioactive impurities emitting α-rays in concentrations of 50 ppb or less, said low melting point metallic film being connected to said mounting substrate.

15. The semiconductor device according to claim 9, which further comprising a filling resin with which a gap between said semiconductor element and said mounting substrate is filled.

16. The semiconductor device according to claim 10, which further comprising a filling resin with which a gap between said semiconductor element and said mounting substrate is filled.

17. The semiconductor device according to claim 9, wherein a package of said semiconductor device comprises said mounting substrate, spacers located around said semiconductor element at a distance, a cover plate over said semiconductor element mounted on said mounting substrate, and an adhesive bonding them.

18. The semiconductor device according to claim 10, wherein a package of said semiconductor device comprises said mounting substrate, spacers located around said semiconductor element at a distance, a cover plate over said semiconductor element mounted on said mounting substrate, and an adhesive bonding them.
